(19) United States
(12) Patent Application Publication
(10) Pub. No.: US 2011/0233718 A1
(43) Pub. Date: Sep. 29, 2011

(54) Heterogeneous Technology Integration

(75) Inventors: Jonghae Kim, San Diego, CA (US); Evgeni P. Gousev, San Jose, CA (US); Matthew Michael Nowak, San Diego, CA (US)

(73) Assignee: QUALCOMM Incorporated, San Diego, CA (US)

(21) Appl. No.: 12/731,520

(22) Filed: Mar. 25, 2010

(51) Int. Cl. H01L 23/52; H01L 23/488; H01L 23/48; H01L 21/70; H01L 23/49

(52) U.S. Cl. 257/506; 257/737; 257/774; 438/121; 257/784; 257/E21.532; 257/E23.141; 257/E23.024; 257/E23.023; 257/E23.011

(57) ABSTRACT

A heterogeneous integrated circuit having at least one tier made of multiple technologies and a method of making the heterogeneous integrated circuit. The heterogeneous integrated circuit includes a package substrate, a first die of a first technology, and a second die of a second technology, where the two dies are located in the same tier. One die can surround the other die. The heterogeneous integrated circuit can also include a wire-bond and/or horizontal micro-bump coupling the two dies. The heterogeneous integrated circuit can also include a wire bond or vertical micro-bump coupling one of the dies to the package substrate. The vertical micro-bump coupling can include a through-via. The two technologies can be any of various technologies including CMOS, glass, sapphire and quartz. One die can also be adjacent to the other die on the same tier and the two dies coupled using a horizontal micro-bump.

### FIELD OF DISCLOSURE

The present disclosure relates generally to integrated circuit packaging, and more specifically to integration of heterogeneous technologies into an integrated circuit package.

### BACKGROUND

Integrated circuits can be designed using different technologies, for example complementary metal oxide semiconductor (CMOS) technology, glass technology, sapphire technology, quartz technology, etc. These different technologies have different properties that make them better suited for different applications. For example, CMOS technology is well suited for active components, such as transistors, which can shrink as feature sizes shrink. However, passive components, such as inductors, do not shrink with feature size and can thus consume a significant amount of space in CMOS technology. As another example, glass technology is not well suited for active devices, but since it can be less expensive than CMOS technology, can be better suited for passive devices. There are various other properties that distinguish the various technologies which are known to those of skill in the art.

Due to the different properties of the various technologies that can be used in integrated circuits, it may be desirable to use more than one technology in the design of an integrated circuit. Use of dies made with different technologies in an integrated circuit can involve stacking of the multiple technology dies, which increases the packaging height of the integrated circuit, and can involve the use of wire-bonds, which can introduce parasitic components. As devices continue to add functionality and shrink in size, it is desirable to minimize packaging height and parasitic components of integrated circuits.

FIGS. 1-3 show an exemplary use of multiple die technologies to form an integrated circuit. FIG. 1 shows a CMOS technology die 100 which includes a silicon die substrate 102, a device layer 104, and multiple back-end of line (BEOL) layers 106. FIG. 2 shows a glass technology die 200 which includes a glass die substrate 202, a device layer 204, and multiple back-end of line (BEOL) layers 206. Note some of the different properties of the silicon die substrate 102 and the glass die substrate 202. The silicon die substrate 102 has lower resistivity and a dielectric constant of about 11, while the glass die substrate 202 has higher resistivity and a lower dielectric constant of about 4.7.

FIG. 3 shows an integrated circuit (IC) 300 that includes the CMOS technology die 100, the glass technology die 200 and a package substrate 302. In the exemplary integrated circuit 300, the glass technology die 200 is in a first tier mounted on the package substrate 302, and the CMOS technology die 100 is in a second tier mounted on the glass technology die 200. The integrated circuit 300 also includes upper bond-wires 310 and lower bond-wires 312. The upper bond-wires 310 couple components on the CMOS technology die 100 with components on the glass technology die 200. The lower bond-wires 312 couple components on the glass technology die 200 with components on the package substrate 302. Thus, a connection from the CMOS technology die 100 to the package substrate 302 must pass through one of the upper bond-wires 310, coupling components on the CMOS technology die 100 with components on the glass technology die 200, and one of the lower bond-wires 312, coupling components on the glass technology die 200 with components on the package substrate 302. These bond-wires 310, 312 introduce parasitic elements that can degrade input/output performance and other attributes of the integrated circuit 300. Note also that the integrated circuit 300 has a packaging height h due to the dies and package substrate which is the sum of the heights of the CMOS technology die 100 on the second tier plus the glass technology die 200 on the first tier plus the package substrate 302. A total packaging height H also includes the additional height due to the bond wires 310 and 312. More complicated integrated circuits can include even more dies of various technologies on more tiers, which lead to increased packaging height and more bond-wires.

It would be desirable to integrate multiple dies of different technologies, heterogeneous dies, into an integrated circuit that has a smaller height than the combined heights of the individual dies in the integrated circuit. It would also be desirable to decrease the number of bond-wires coupling the multiple dies in order to decrease the parasitic elements of the integrated circuit.

### SUMMARY

The present invention can reduce the packaging height of a heterogeneous technology integrated circuit. Alternatively or in addition, the present invention can eliminate some or all of the bond-wires between the various dies and between the dies and the package substrate which can reduce the parasitic components of the heterogeneous technology integrated circuit.

One embodiment of a heterogeneous integrated circuit includes a package substrate, a first die of a first technology, and a second die of a second technology. In this embodiment, the first die and the second die are both coupled to the package substrate in the same tier of the heterogeneous integrated circuit, and the second die surrounds multiple sides of the first die. The second die can surround all sides of the first die. The heterogeneous integrated circuit can include a die wire-bond and/or a horizontal micro-bump coupling the first die to the second die. The heterogeneous integrated circuit can include a substrate wire-bond coupling one of the first die and the second die to the package substrate. The heterogeneous integrated circuit can include a vertical micro-bump coupling a coupled die to the package substrate, the coupled die being one of the first die or the second die. The coupled die can include a through-via coupled to the vertical micro-bump. In one exemplary embodiment of the heterogeneous integrated circuit, the first technology and the second technology are each one of CMOS technology, glass technology, sapphire technology and quartz technology; and the first technology is different from the second technology. In one exemplary embodiment of the heterogeneous integrated circuit, the first technology is CMOS technology and the second technology is glass technology.

An alternative embodiment of a heterogeneous integrated circuit also includes a package substrate, a first die of a first technology, and a second die of a second technology. In this embodiment, the first die and the second die are both coupled to the package substrate, are in the same tier of the heterogeneous integrated circuit, and a horizontal micro-bump that does not contact the package substrate is used to couple the first die to the second die. The heterogeneous integrated circuit can include a substrate wire-bond coupling one of the first die and the second die to the package substrate. The heterogeneous integrated circuit can include a vertical micro-bump coupling a coupled die to the package substrate, the coupled die being one of the first die or the second die. The coupled die can include a through-via coupled to the vertical micro-bump. In one exemplary embodiment of the heterogeneous integrated circuit, the first technology and the second technology are each one of CMOS technology, glass technology, sapphire technology and quartz technology; and the first technology is different from the second technology. In one exemplary embodiment of the heterogeneous integrated circuit, the first technology is CMOS technology and the second technology is glass technology.

The heterogeneous integrated circuit can be made by placing a first die of a first technology in a particular tier of the heterogeneous integrated circuit coupled to a package substrate, and placing a second die of a second technology in the particular tier of the heterogeneous integrated circuit coupled to the package substrate, the second die surrounding multiple sides of the first die, where the first technology is different from the second technology. The second die can surround all sides of the first die. The making of the heterogeneous integrated circuit can also include coupling the first die to the second die using a horizontal micro-bump or a wire-bond. The making of the heterogeneous integrated circuit can also include coupling one of the first die and the second die to the substrate using a vertical micro-bump or a wire-bond.

For a more complete understanding of the present disclosure, reference is now made to the following detailed description and the accompanying drawings.

### BRIEF DESCRIPTION OF THE DRAWINGS

FIG. 1 is an exemplary complementary metal oxide semiconductor (CMOS) technology die;

FIG. 2 is an exemplary glass technology die;

FIG. 3 is an exemplary heterogeneous technology integrated circuit that includes a CMOS technology die and a glass technology die;

FIG. 4 is an exemplary heterogeneous technology integrated circuit that includes a first die of a first technology adjacent to a second die of a second technology, the first die and the second die being on the same tier;

FIG. 5 is an exemplary heterogeneous technology integrated circuit that includes a first die of a first technology surrounded on multiple sides by a second die of a second technology, the first die and the second die being on the same tier;

FIG. 6 is an exemplary heterogeneous technology integrated circuit that includes a first die of a first technology surrounded on all sides by a second die of a second technology, the first die and the second die being on the same tier;

FIG. 7 is another exemplary heterogeneous technology integrated circuit that includes a first die of a first technology surrounded on all sides by a second die of a second technology, the first die and the second die being on the same tier;

FIG. 8 is a cross-section of the exemplary heterogeneous technology integrated circuit of FIG. 7;

FIG. 9 is a cross-section of another exemplary heterogeneous technology integrated circuit that includes a first die of a first technology, a second die of a second technology, and vertical micro-bumps, the first die and the second die being on the same tier;

FIG. 10 is an exemplary die with a through-via;

FIG. 11 is yet another exemplary heterogeneous technology integrated circuit that includes a first die of a first technology, a second die of a second technology, and horizontal micro-bumps, the first die and the second die being on the same tier;

FIG. 12 is a top-view of a horizontal micro-bump coupling a component or circuit portion on a first die to a component or circuit portion on a second die;

FIG. 13 is a flow diagram of an exemplary method for making a heterogeneous integrated circuit; and

FIG. 14 is a block diagram showing an exemplary wireless communication system in which a heterogeneous technology integrated circuit may be advantageously employed.

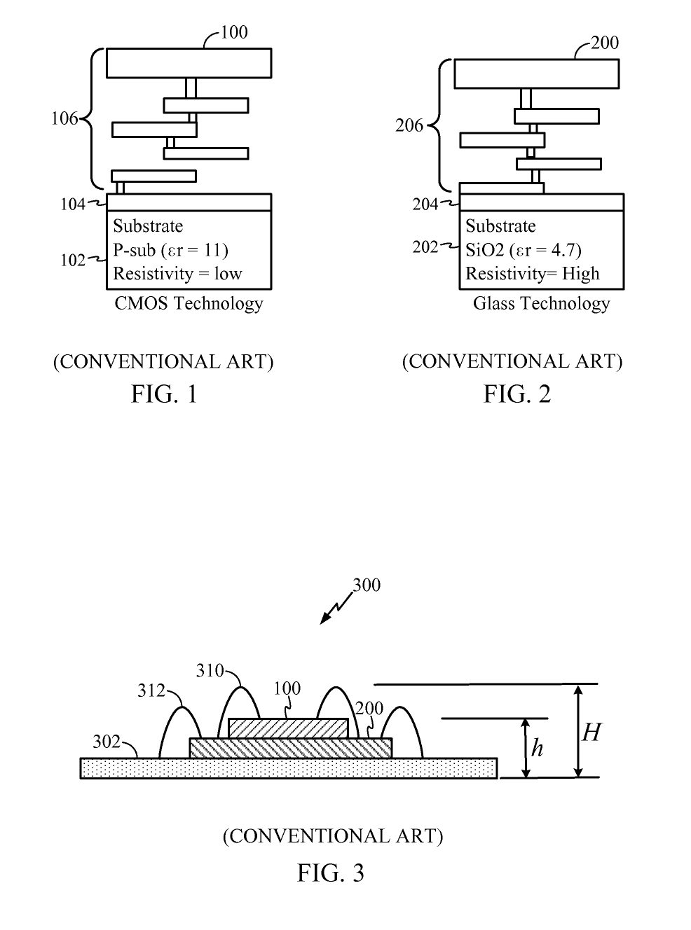

### DETAILED DESCRIPTION

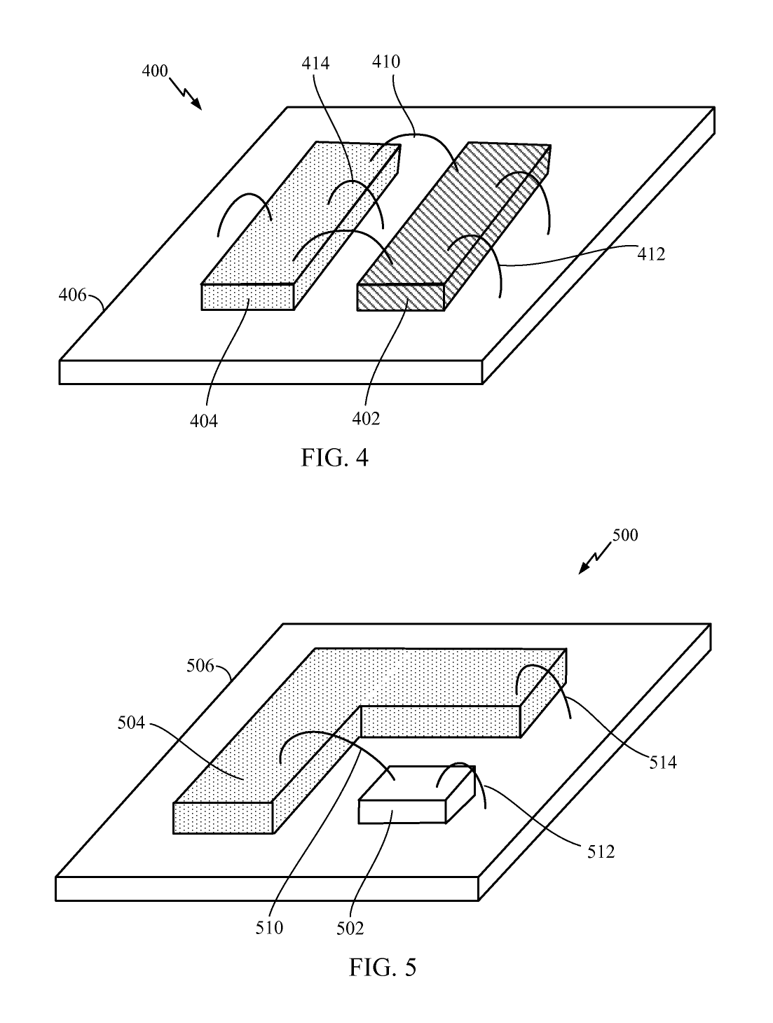

FIG. 4 shows an exemplary embodiment of a heterogeneous technology integrated circuit 400. The heterogeneous technology integrated circuit 400 includes a first die 402 of a first technology, a second die 404 of a second technology, and a package substrate 406. The first technology and second technology are different, thus the integrated circuit 400 is of heterogeneous technologies. Examples of different technologies include complementary metal oxide semiconductor (CMOS) technology, glass technology, sapphire technology, quartz technology, etc. Thus, the first die 402 could be a CMOS technology die and the second die 404 could be a glass technology die.

Both the first die 402 and the second die 404 are on the same tier, and both the first die 402 and the second die 404 are mounted on the package substrate 406. The second die 404 is mounted on the package substrate 406 adjacent to the first die 402. The first die 402 is coupled to the second die 404 by die wire-bonds 410, the first die 402 is coupled to the package substrate 406 by first substrate wire-bonds 412, and the second die 404 is coupled to the package substrate 406 by second substrate wire-bonds 414.

FIG. 5 shows another exemplary embodiment of a heterogeneous technology integrated circuit 500. The heterogeneous technology integrated circuit 500 includes a first die 502 of a first technology, a second die 504 of a second technology, and a package substrate 506. The first technology and second technology are different, thus the integrated circuit 500 is of heterogeneous technologies. Both the first die 502 and the second die 504 are on the same tier, and both the first die 502 and the second die 504 are mounted on the package substrate 506. The second die 504 surrounds multiple sides of the perimeter of the first die 502. The first die 502 is coupled to the second die 504 by die wire-bonds 510, the first die 502 is coupled to the package substrate 506 by first substrate wire-bonds 512, and the second die 504 is coupled to the package substrate 506 by second substrate wire-bonds 514.

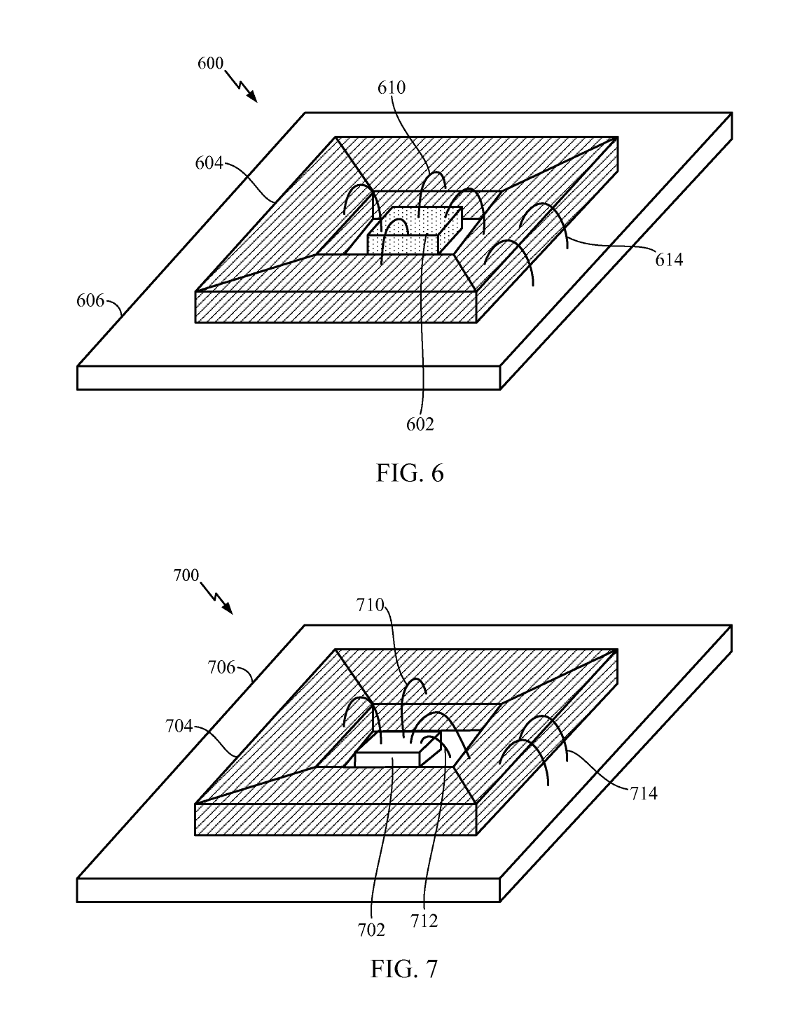

FIG. 6 shows an exemplary embodiment of a heterogeneous technology integrated circuit 600. The heterogeneous technology integrated circuit 600 includes a first die 602 of a first technology, a second die 604 of a second technology, and a package substrate 606. The first technology and second technology are different, thus the integrated circuit 600 is of heterogeneous technologies. Both the first die 602 and the second die 604 are on the same tier, and both the first die 602 and the second die 604 are mounted on the package substrate 606. The second die 604 surrounds the first die 602 on all sides. The first die 602 is coupled to the second die 604 by die wire-bonds 610, and the second die 604 is coupled to the package substrate 606 by second substrate wire-bonds 612.

FIG. 7 shows another exemplary embodiment of a heterogeneous technology integrated circuit 700. The heterogeneous technology integrated circuit 700 includes a first die 702 of a first technology, a second die 704 of a second technology, and a package substrate 706. Both the first die 702 and the second die 704 are on the same tier. Both the first die 702 and the second die 704 are mounted on the package substrate 706, and the second die 704 surrounds the first die 702. The first die 702 is coupled to the second die 704 by die wire-bonds 710, and the second die 704 is coupled to the package substrate 706 by second substrate wire-bonds 712. FIG. 7 also shows the first die 702 coupled to the package substrate 706 by first substrate wire-bonds 714. Thus in FIG. 7, the first die 702 can be coupled to the package substrate 706 using a single wire-bond, one of the first substrate wire-bonds 714. In contrast, in embodiment of FIG. 6, coupling the first die 602 to the package substrate 606 includes one of the die wire-bonds 610 coupling the first die 602 to the second die 604, an on-die connection in the second die 604 coupling one of the die wire-bonds 610 to one of the second substrate wire-bonds 612, and one of the second substrate wire-bonds 612 coupling the second die 604 to the package substrate 606. The more direct connection through one of the first substrate wire-bonds 714 can reduce the parasitic effects of the wire-bonds.

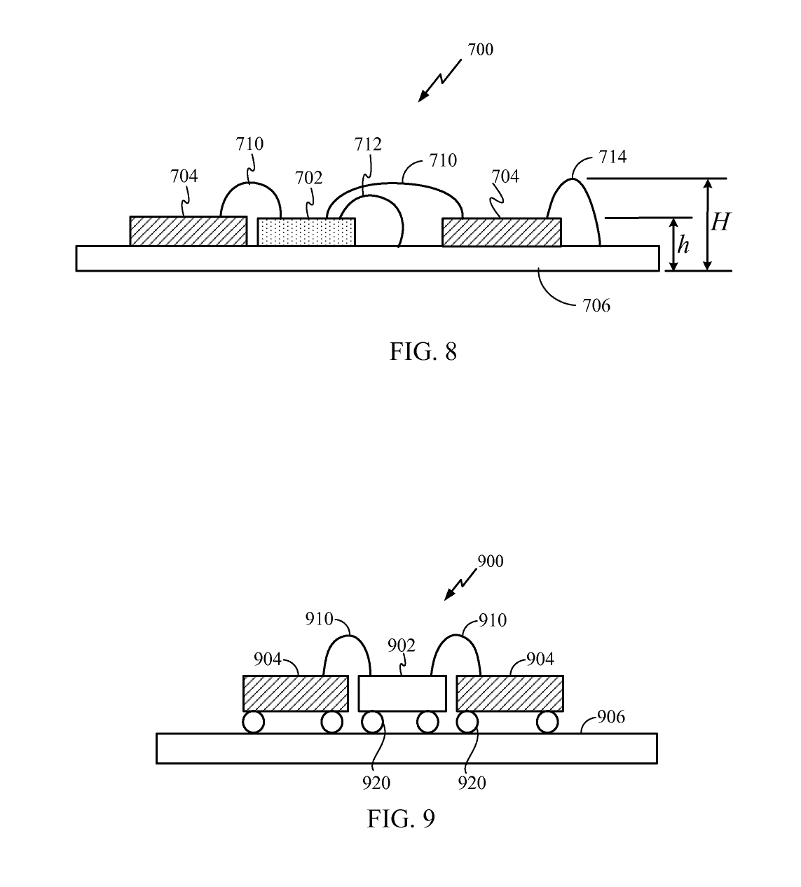

FIG. 8 shows a cross-section of the heterogeneous technology integrated circuit 700 through the first die 702, the second die 704 and the package substrate 706. Both the first die 702 and the second die 704 are on the same tier, and both the first die 702 and the second die 704 are mounted on the package substrate 706. The second die 704 surrounds the first die 702 on all sides. The first die 702 is coupled to the second die 704 by die wire-bonds 710, the first die 702 is coupled to the package substrate 706 by the first substrate wire-bonds 714, and the second die 704 is coupled to the package substrate 706 by the second substrate wire-bonds 712.

The packaging height or thickness of the heterogeneous integrated circuit 700 (like that of the heterogeneous integrated circuits 400, 500 and 600) is approximately the sum of the height of the package substrate 706 and the greater of the heights of the first die 702 and the second die 704, plus any additional height due to the bond wires 710, 712 and 714. For exemplary purposes only, assume the package substrate 706, the first die 702 and the second die 704 have the same thickness t. In this case, the packaging height of the one tier embodiment shown in FIG. 7 due to the dies and package substrate h=2t. However the packaging height of the prior art two tier embodiment shown in FIG. 3 due to the dies and package substrate h=3t. Thus in this case, the one tier heterogeneous integrated circuit shown in FIG. 7 has a packaging height due to dies and package substrate that is approximately one-third less than the conventional two tier embodiment shown in FIG. 3. The total packaging height H of either embodiment can have additional height due to wire-bonds.

FIG. 9 shows a cross-section of another exemplary embodiment of a heterogeneous technology integrated circuit 900. The heterogeneous technology integrated circuit 900 includes a first die 902 of a first technology, a second die 904 of a second technology, and a package substrate 906. The first technology and second technology are different, thus the integrated circuit 900 is of heterogeneous technologies. Both the first die 902 and the second die 904 are on the same tier, and both the first die 902 and the second die 904 are mounted on the package substrate 906. The second die 904 surrounds the first die 902 on multiple sides. The first die 902 is coupled to the second die 904 by die wire-bonds 910. The first die 902 and/or the second die 904 are coupled to the package substrate 906 through vertical micro-bumps 920. The vertical micro-bumps 920 can be used to replace any of the first substrate wire-bonds 412, 512 or 712; or any of the second substrate wire-bonds 414, 514, 614 or 714. The vertical micro-bumps may introduce less parasitic components than the wire-bonds.

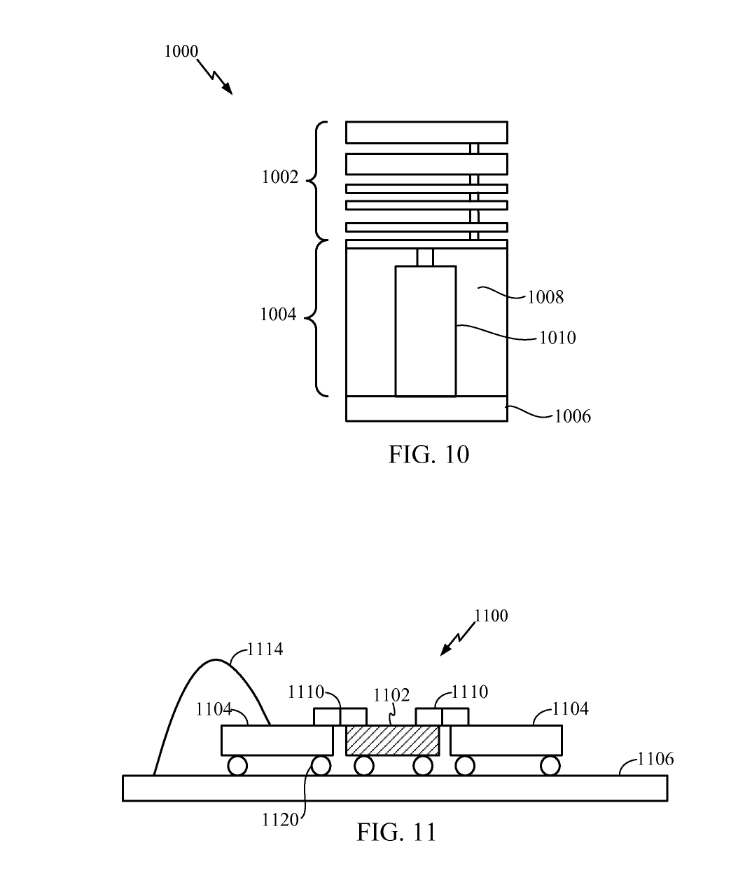

One way of using the vertical micro-bumps 920 to couple circuits on the dies 902, 904 to the package substrate 906 is through the use of through vias. FIG. 10 illustrates an exemplary die 1000 of a particular technology that could be either of the first die 902 or the second die 904 of the heterogeneous technology integrated circuit 900. The die 1000 includes a back-end of line (BEOL) section 1002, a front-end of line (FEOL) section 1004 and a redistributed design layer (RDL) 1006. The FEOL section 1004 includes a die substrate 1008. A through via 1010 extends through the die substrate 1008 and can couple circuits in the FEOL section 1004 and the BEOL section 1002 to the RDL layer 1006. Thus, using the exemplary die 1000 as either the first die 902 or the second die 904 of the heterogeneous technology integrated circuit 900, a FEOL circuit can be coupled to the package substrate 906 using the through via 1010 and the vertical micro-bump 920. By way of example, the through via 1010 could be a through-silicon via (TSV) if the die substrate is composed of silicon (but not glass), or a through-glass via (TGV) if the die substrate is composed of glass.

FIG. 11 shows a cross-section of another exemplary embodiment of a heterogeneous technology integrated circuit 1100. The heterogeneous technology integrated circuit 1100 includes a first die 1102 of a first technology, a second die 1104 of a second technology, and a package substrate 1106. The first technology and second technology are different, thus the integrated circuit 1100 is of heterogeneous technologies. Both the first die 1102 and the second die 1104 are on the same tier, and both the first die 1102 and the second die 1104 are coupled to the package substrate 1106 without passing through an intervening die. The second die 1104 can surround multiple sides of the first die 1102. The first die 1102 and/or the second die 1104 can be coupled to the package substrate 1106 using vertical micro-bumps 1120 and/or using substrate wire-bonds 1114. The first die 1102 is coupled to the second die 1104 through horizontal micro-bumps 1110. The horizontal micro-bumps 1110 can be used to replace any of the die wire-bonds 410, 510, 610, 710 or 910.

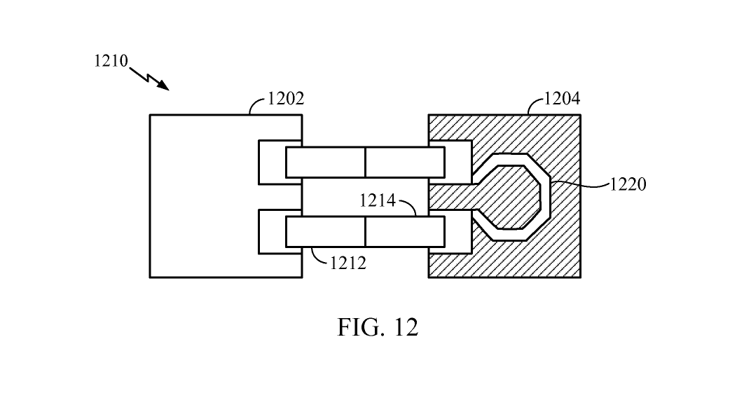

FIG. 12 shows a larger top-view of a horizontal micro-bump 1210, like the horizontal micro-bump 1110 of FIG. 11. The horizontal micro-bump 1210 includes a first port 1212 coupled to a first die 1202 and a second port 1214 coupled to a second die 1204. In the horizontal micro-bump 1210, the first port 1212 is also coupled to the second port 1214. Thus, the horizontal micro-bump 1210 creates a connection between the first die 1202 to the second die 1204. FIG. 12 shows an exemplary connection of the two inputs of an inductor 1220 on the second die 1204 to two nodes of a circuit on the first die 1202. The horizontal micro-bumps 1210 reduce the packaging height necessary to accommodate the wire-bonds and can also reduce the parasitic elements introduced by the wire-bonds. The horizontal micro-bumps 1210 can be shorter than the wire-bonds, for example, a wire bond can be about 1 mm whereas the horizontal micro-bump 1210 can be about 300 μm.

The horizontal micro-bump 1210 can be used when the first die 1202 is adjacent to or surrounded on multiple sides by the second die 1204. For example, as shown in FIG. 12, a horizontal micro-bump 1210 can be used to couple an element or circuit portion on a first die 1202 with an element or circuit portion on an adjacent die 1204.

Any of the embodiments of heterogeneous integrated circuits shown above can include multiple tiers. Additional tiers could be present between the package substrate and the tier containing both the first and second dies. Alternatively, there could be multiple tiers above the tier containing both the first and second dies. In these cases, wire-bonds, vertical micro-bumps, horizontal micro-bumps or other connectors can be used to couple the various tiers to one another and to the package substrate.

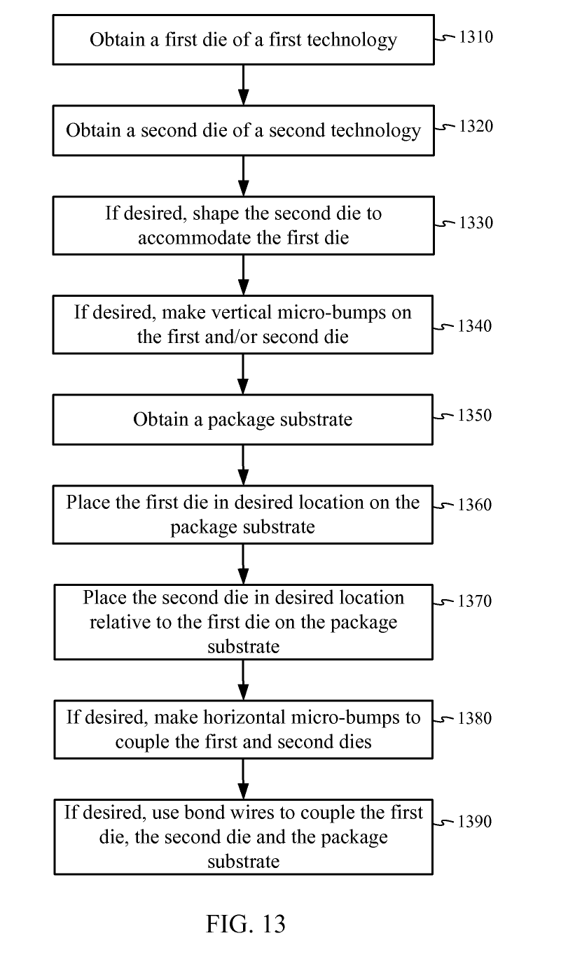

A heterogeneous integrated circuit like the exemplary embodiments described above in FIGS. 4-9, 11 and 12 could be made by various methods. An exemplary method, by way of example and not limitation, is shown in FIG. 13. At block 1310, a first die using a first technology is obtained. At block 1320, a second die using a second technology is obtained. Block 1330 is performed in cases where it may be necessary to shape or make an opening in the second die to accommodate a desired placement relative to the first die. Alternatively, block 1330 may be unnecessary when the second die can be obtained that already has the desired shape or opening. If desired, block 1340 is performed to make vertical micro-bumps, such as vertical micro-bumps 920, on one or both of the first and second dies.

At block 1350, a package substrate is obtained. At block 1360, the first die is placed in its desired location on the package substrate. At block 1370, the second die is placed in its desired location relative to the first die on the package substrate. During placement of the first and second dies in blocks 1360 and 1370, any die(s) having vertical micro-bumps are placed such that the vertical micro-bumps make the proper connection between the die and the package substrate.

If desired, block 1380 is performed to make horizontal micro-bumps, such as horizontal micro-bumps 1110, to couple the first die and the second die. If desired, block 1390 is performed to add bond wires to couple the first die to the second die; or to couple the first die to the package substrate; or to couple the second die to the package substrate. Note that the first die and/or the second die could also be coupled to the package substrate using through-vias.

Those of skill in the art will understand that there are numerous variations that could be made to the exemplary method shown in FIG. 13. For example, the order of obtaining or placing of the various components could be rearranged; or the second die could be placed on the package substrate prior to the first die, such that the first die is placed relative to the second die; or the placement of the horizontal micro-bumps and the bond wires could be rearranged; and other variations could be also made to the method.

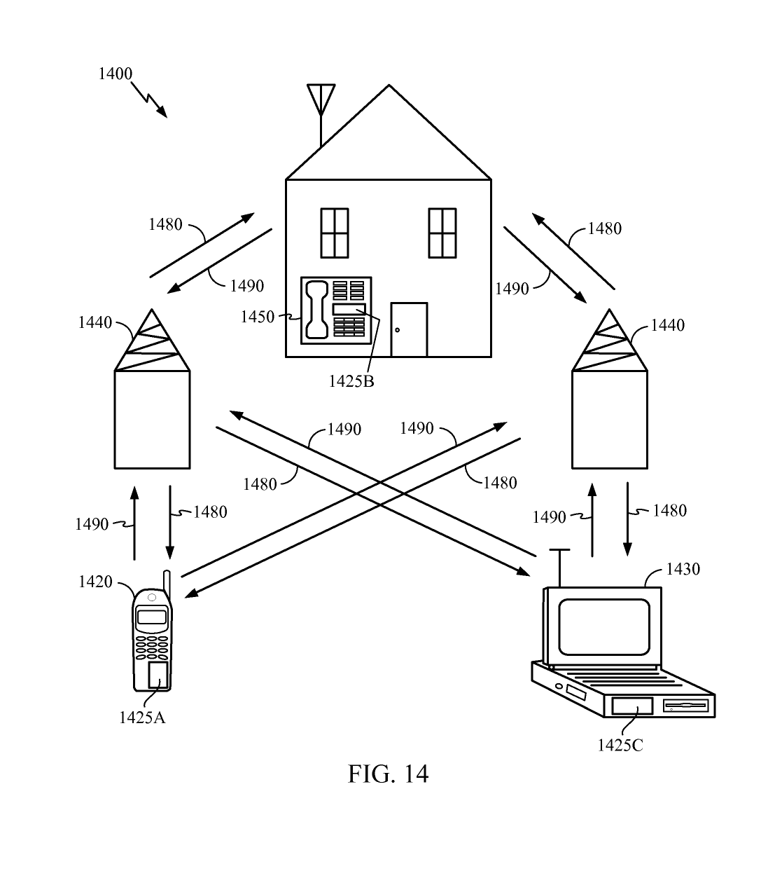

FIG. 14 shows an exemplary wireless communication system 1400 in which an embodiment of a heterogeneous technology integrated circuit may be advantageously employed. The heterogeneous integrated circuit can include multiple dies of different technologies on the same tier, and/or may include vertical micro-bumps, and/or may include horizontal micro-bumps, and/or may include bond wires. For purposes of illustration, FIG. 14 shows three remote units 1420, 1430, and 1450 and two base stations 1440. It should be recognized that typical wireless communication systems may have many more remote units and base stations. Any of remote units 1420, 1430, and 1450 may include heterogeneous integrated circuit as disclosed herein. FIG. 14 shows forward link signals 1480 from the base stations 1440 and the remote units 1420, 1430, and 1450 and reverse link signals 1490 from the remote units 1420, 1430, and 1450 to base stations 1440.

In FIG. 14, remote unit 1420 is shown as a mobile telephone, remote unit 1430 is shown as a portable computer, and remote unit 1450 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 14 illustrates certain exemplary remote units that may include components having heterogeneous integrated circuits as disclosed herein, the use of heterogeneous integrated circuits is not limited to these exemplary illustrated units. Embodiments may be suitably employed in any electronic device in which heterogeneous integrated circuits as disclosed herein is desired.

While exemplary embodiments incorporating the principles of the present invention have been disclosed hereinabove, the present invention is not limited to the disclosed embodiments. Instead, this application is intended to cover any variations, uses, or adaptations of the invention using its general principles. Further, this application is intended to cover such departures from the present disclosure as come within known or customary practice in the art to which this invention pertains and which fall within the limits of the appended claims.

We claim:

1. A heterogeneous integrated circuit having at least one tier, the heterogeneous integrated circuit comprising:
a package substrate;
a first die of a first technology coupled to the package substrate in a particular tier of the heterogeneous integrated circuit; and
a second die of a second technology coupled to the package substrate in the particular tier of the heterogeneous integrated circuit, the second die surrounding multiple sides of the first die, the second technology being different from the first technology.

2. The heterogeneous integrated circuit of claim 1, wherein the second die surrounds all sides of the first die.

3. The heterogeneous integrated circuit of claim 1, further comprising a die wire-bond coupling the first die to the second die.

4. The heterogeneous integrated circuit of claim 1, further comprising a vertical micro-bump coupling a coupled die to the package substrate, the coupled die being one of the first die and the second die.

5. The heterogeneous integrated circuit of claim 4, wherein the coupled die includes a through-via coupled to the vertical micro-bump.

6. The heterogeneous integrated circuit of claim 4, further comprising a horizontal micro-bump coupling the first die to the second die.

7. The heterogeneous integrated circuit of claim 1, further comprising a horizontal micro-bump coupling the first die to the second die.

8. The heterogeneous integrated circuit of claim 1, wherein the first technology is CMOS technology and the second technology is glass technology.

9. The heterogeneous integrated circuit of claim 1, wherein the first technology and the second technology are each one of CMOS technology, glass technology, sapphire technology and quartz technology.

10. A heterogeneous integrated circuit having at least one tier, the heterogeneous integrated circuit comprising:
a package substrate;
a first die of a first technology coupled to the package substrate in a particular tier of the heterogeneous integrated circuit;
a second die of a second technology coupled to the package substrate in the particular tier of the heterogeneous integrated circuit, and
a horizontal micro-bump coupling the first die to the second die without passing through the package substrate.

11. The heterogeneous integrated circuit of claim 10, further comprising a substrate wire-bond coupling one of the first die and the second die to the package substrate.

12. The heterogeneous integrated circuit of claim 10, further comprising a vertical micro-bump coupling a coupled die to the package substrate, the coupled die being one of the first die and the second die.

13. The heterogeneous integrated circuit of claim 12, wherein the coupled die includes a through-via coupled to the vertical micro-bump.

14. The heterogeneous integrated circuit of claim 10, wherein the first technology is CMOS technology and the second technology is glass technology.

15. The heterogeneous integrated circuit of claim 10, wherein the first technology and the second technology are each one of CMOS technology, glass technology, sapphire technology and quartz technology; and the first technology is different from the second technology.

16. A method of making a heterogeneous integrated circuit having at least one tier, the method comprising:
placing a first die of a first technology in a particular tier of the heterogeneous integrated circuit coupled to a package substrate; and
placing a second die of a second technology in the particular tier of the heterogeneous integrated circuit coupled to the package substrate; the second die surrounding multiple sides of the first die; the second technology being different from the first technology.

17. The method of claim 16, wherein the second die surrounds all sides of the first die.

18. The method of claim 16, further comprising coupling the first die to the second die using a horizontal micro-bump.

19. The method of claim 16, further comprising coupling one of the first die and the second die to the package substrate using a vertical micro-bump.

20. The method of claim 16, further comprising coupling one of the first die and the second die to the package substrate using a wire-bond.
